(19) United States
(12) Patent Application Publication
(10) Pub. No.: US 2008/0160655 A1
(43) Pub. Date: Jul. 3, 2008

(54) Method of verifying line reliability and method of manufacturing semiconductor device

(76) Inventor: Ji Ho Hong, Hwaseong-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/930,278

(22) Filed: Oct. 31, 2007

(30) Foreign Application Priority Data
Dec. 27, 2006 (KR) 10-2006-0135753

(51) Int. Cl. H01L 21/66; H01L 21/4763

(52) U.S. Cl. 438/16; 438/653; 257/E21.53; 257/E21.575

(57) ABSTRACT

Provided are a method of verifying line reliability and a method of fabricating a semiconductor substrate to improve the line reliability. The semiconductor device fabricating method includes: forming an interlayer insulating layer having a via hole on a semiconductor substrate; forming a seed layer on the interlayer insulating layer; performing an ammonia plasma process on the seed layer to reduce the surface of the seed layer; and forming a copper line using the surface roughness reduced seed layer.

### CROSS-REFERENCE TO RELATED APPLICATION

The present application claims the benefit under 35 U.S.C. §119 of Korean Patent Application No. 10-2006-0135753, filed Dec. 27, 2006, which is hereby incorporated by reference in its entirety.

### BACKGROUND

In order to highly integrate a semiconductor device and improve the performance thereof, a multilayer structured metal line was widely used. Although aluminum metal lines had been generally used, recently copper metal lines having are being widely used.

Since it is not easy to pattern a copper line, a damascene process or a chemical mechanical polishing (CMP) process is generally performed to form the copper line.

FIG. 1A to FIG. 1C are cross-sectional views for illustrating a method of fabricating a semiconductor device according to the related art.

Referring to FIG. 1A, an interlayer insulating layer 3 is formed on a semiconductor substrate 1. Then, a via hole 2 is formed by patterning the interlayer insulating layer 3.

A barrier layer 5 is formed to prevent copper from being diffused on the semiconductor substrate 1 having the via hole 2.

Then, a seed layer 7 is formed to easily fill the copper in the via hole 2.

Referring to FIG. 1B, the copper material 8 is deposited with the seed layer 7 as a plating medium.

Referring to FIG. 1C, a copper line 9 is formed in the via hole 2 by performing a chemical mechanical polishing (CMP) process.

Although the copper line can be formed as described above, the relationship between the seed layer and the copper line is not yet defined. Particularly, it is not defined as to how the reliability of the copper line is affected according to the surface roughness of the seed layer.

### BRIEF SUMMARY

Embodiments of the present invention provide a method of verifying line reliability in order to verify the relationship between the surface roughness of a seed layer and line reliability.

Embodiments of the present invention also provide a method of fabricating a semiconductor device for improving line reliability based on a method of verifying line reliability.

In one embodiment, a method of verifying line reliability includes: providing a first substrate and a second substrate; forming seed layers on the first substrate and the second substrate; forming different surface roughness on each of the seed layers; performing a first x-ray diffraction (XRD) analysis on each of the seed layers; forming a copper line on each of the seed layers; performing a second XRD analysis on each of the copper lines; and defining line reliability based on the results of the first and second XRD analysis.

In another embodiment, a method of fabricating a semiconductor device includes: forming an interlayer insulating layer having a via hole on a semiconductor substrate; forming a seed layer on the interlayer insulating layer; performing an ammonia plasma process on the seed layer to provide the seed layer with a small surface roughness; and forming a copper line using the surface roughness reduced seed layer.

The details of one or more embodiments are set forth in the accompanying drawings and the description below. Other features will be apparent from the description and drawings, and from the claims.

### BRIEF DESCRIPTION OF THE DRAWINGS

FIG. 1A to FIG. 1C are cross-sectional views for illustrating a method for fabricating a semiconductor device according to the related art.

FIG. 2 is a flowchart for illustrating a method for verifying line reliability according to an embodiment of the present invention.

FIG. 3A and FIG. 3B are diagrams illustrating the surface roughness of a seed layer according to an embodiment of the present invention in atomic force microscope (AFM).

FIG. 4A and FIG. 4B are graphs illustrating the copper directivity of a seed layer according to an embodiment of the present invention in X-ray diffraction (XRD).

FIG. 5A and FIG. 5B are graphs illustrating the copper directivity of a copper line according to an embodiment of the present invention in X-ray diffraction (XRD).

FIG. 6A through FIG. 6D are cross-sectional views for describing a method for fabricating a semiconductor device according to an embodiment of the present invention.

FIG. 7 is a diagram illustrating the surface roughness of a seed layer after an ammonia plasma process is performed according to an embodiment of the present invention.

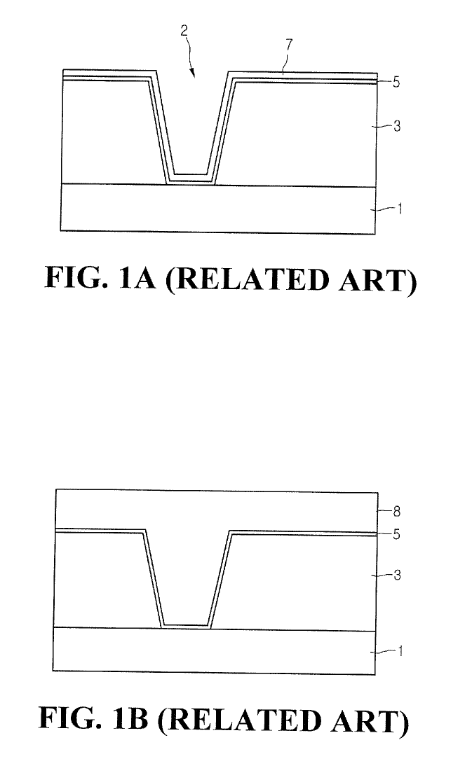

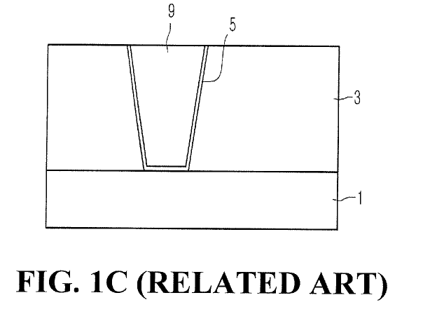

### DETAILED DESCRIPTION

Reference will now be made in detail to embodiments of the present disclosure, examples of which are illustrated in the accompanying drawings.

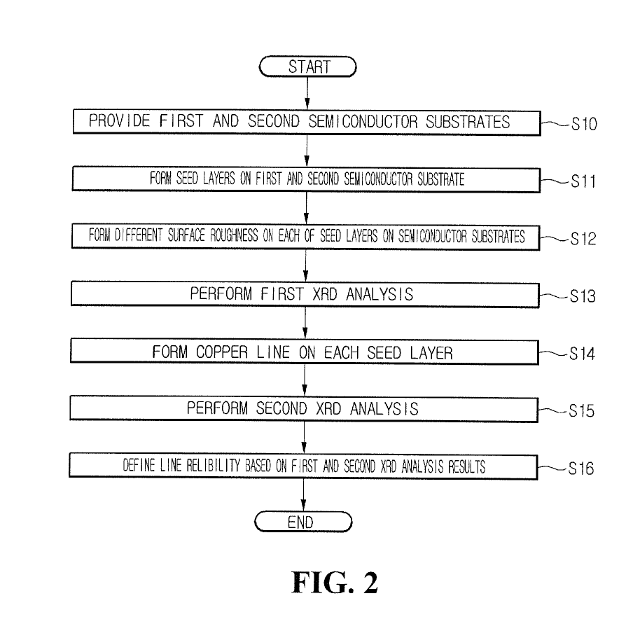

FIG. 2 is a flowchart for illustrating a method for verifying line reliability according to an embodiment of the present invention.

Referring to FIG. 2, a first substrate and a second substrate can be provided (step S10).

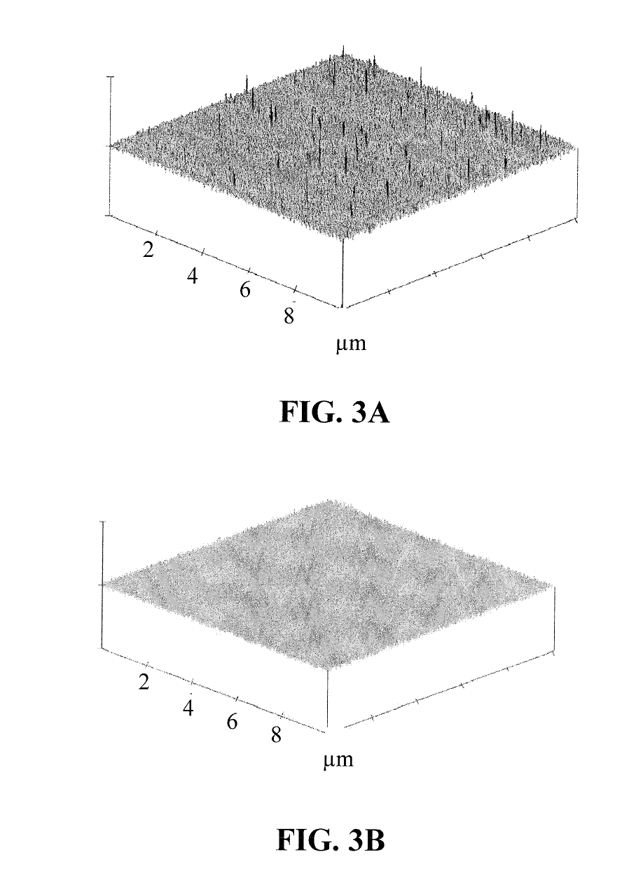

Seed layers can be formed on the first substrate and the second substrate for plating copper (step S11). Each of the seed layers is formed to have different surface roughness by performing a predetermined process or not performing the predetermined process (step S12). The predetermined process may be an ammonia NH₃ plasma process. In one embodiment, the predetermined process can be performed on the second substrate but not on the first substrate. For example, the surface roughness of the seed layer formed on the first substrate can be about 3.929 nm of RMS as shown in FIG. 3A. The surface roughness of the seed layer formed on the second substrate can be about 0.693 nm of RMS as shown in FIG. 3B.

Then, a first X-ray diffraction (XRD) analysis can be performed on the seed layers of the first and second substrate, each of which has the different surface roughness (step S13).

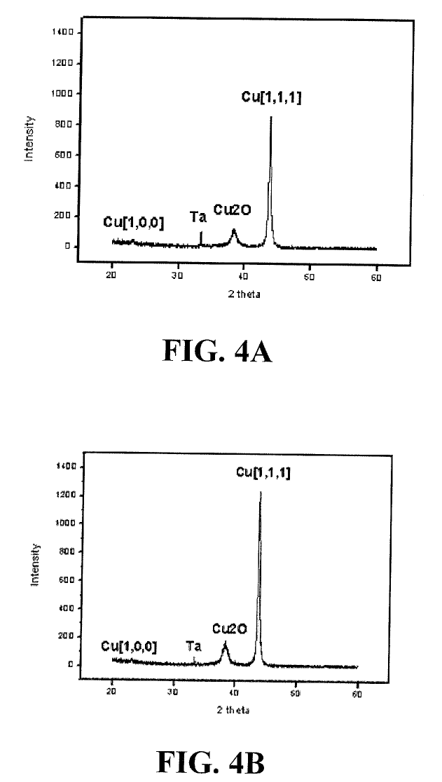

The result of a first XRD analysis of the first and second substrate is shown in FIG. 4A and FIG. 4B, respectively. As shown in FIG. 4A, copper having a directivity of [1,1,1] is weakly detected from the seed layer on the first substrate. As shown in FIG. 4B, copper having a directivity of [1,1,1] is strongly detected from the seed layer on the second substrate.

A copper line can be formed by performing an electrochemical planting process on each of the seed layers at (step S14).

A second XRD analysis can be performed on each of the copper lines on the first and second substrates (step S15).

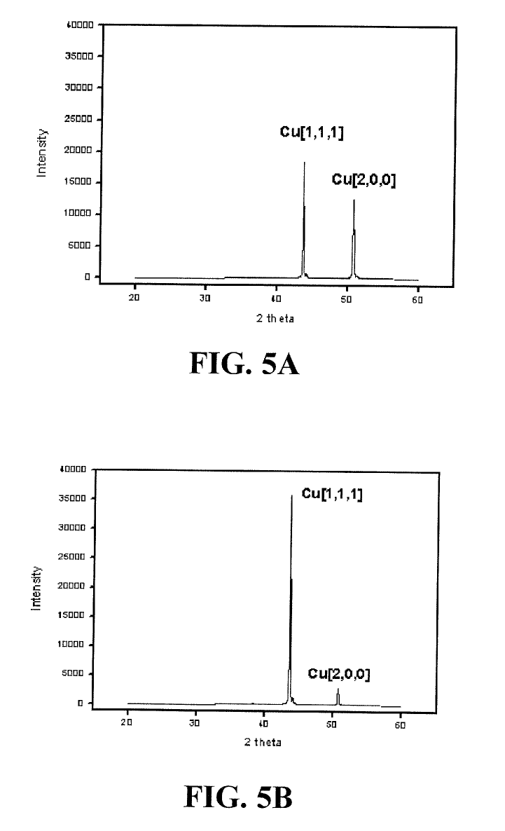

FIG. 5A and FIG. 5B show the result of a second XRD analysis. As shown in FIG. 5A, copper having the directivity of [1,1,1] is weakly detected and copper having the directivity of [2,0,0] is strongly detected from the copper line on the first substrate. As shown in FIG. 5B, copper having the directivity of [1,1,1] is strongly detected and copper having the directivity of is weakly detected from the copper line on the first substrate. The copper line having the directivity of [2,0,0] is a major factor to decide the reliability of the copper line. The reliability of the copper line is reduced as the copper having the directivity of [2,0,0] increases, and the reliability of the copper line increases as the copper having the directivity of [2,0,0] decreases.

Based on the first and second XRD analysis results, the line reliability can be defined (step S16).

Since the copper having the directivity of [2,0,0] directivity is more strongly detected from the copper line on the first substrate than that from the copper line on the second substrate, the reliability of the copper line in the first substrate is lower that that of a copper wire in the second substrate.

A major factor of degrading the reliability of the copper line in the first substrate is that the surface roughness of the seed layer on the first substrate is greater than that of the seed layer on the second substrate.

Therefore, the reliability of a copper line on a seed layer becomes degraded as the surface roughness of the seed layer increases.

In order to improve the reliability of copper line, the surface roughness of the seed layer should be minimized.

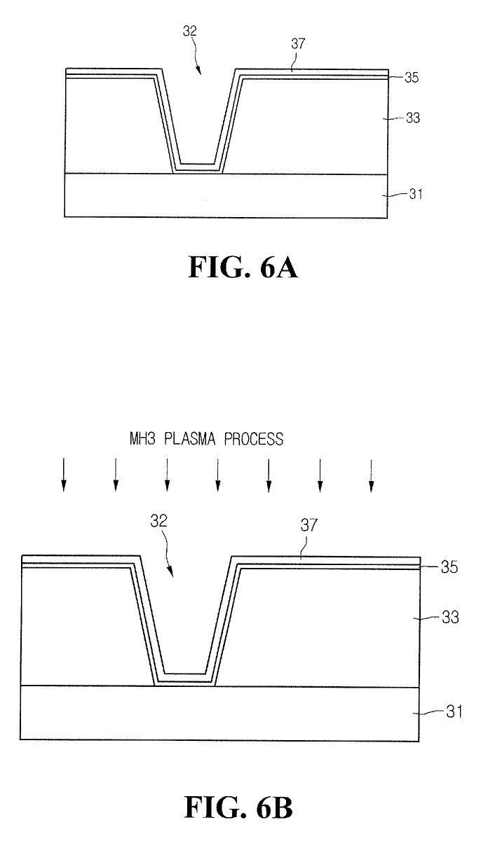

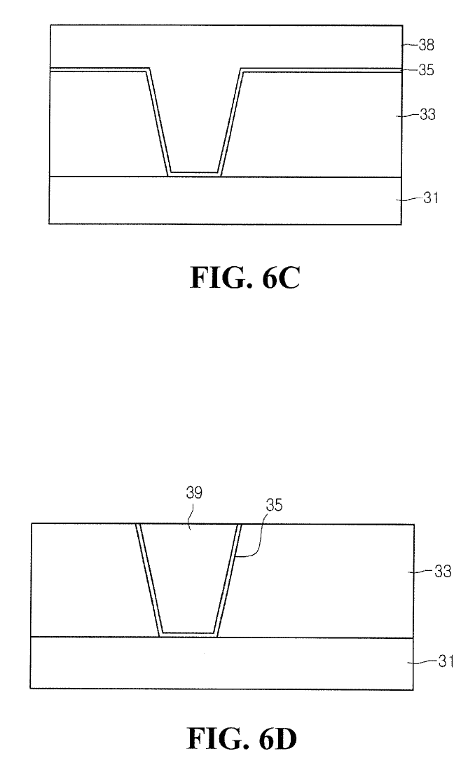

FIG. 6A through FIG. 6D are cross-sectional views for describing a method for fabricating a semiconductor device according to an embodiment.

Referring to FIG. 6A, an interlayer insulating layer 33 can be formed on a semiconductor substrate 31, and a via hole 32 can be formed by patterning the interlayer insulating layer 33. A device for performing a predetermined function, for example, a transistor, a capacitor, or a conductive pattern, can be provided under the interlayer insulating layer 33 on the semiconductor substrate 31.

The interlayer insulating layer 33 can be made of, for example, an undoped silicate glass (USG), a boro-silicate glass (BSG), or a boro-phosphorous silicate glass (BPSG).

Although this embodiment describes a single damascene process having a via hole 32, a dual damascene process having a via hole and a trench communicated with the via hole can be applied.

A barrier layer 35 can be formed to inhibit copper from being diffused into the interlayer insulating layer 33 having the via hole 32. The barrier layer 35 can be made of, for example, Ta or TaN. The barrier layer 35 can inhibit copper from penetrating to a device such as a transistor of the semiconductor substrate 31.

Then, a seed layer 37 can be formed on the barrier layer 35. The seed layer 27 may be formed by performing a sputtering process. However, embodiments are not limited thereto. For example, an electrochemical plating process may be performed to form the seed layer 27.

Referring to FIG. 6B, an ammonia NH₃ plasma process can be performed on the seed layer 37 to reduce the surface roughness of the seed layer 37.

As described above, the surface roughness of the seed layer 37 becomes less rough when the ammonia NH₃ plasma process is performed.

According to an embodiment, the conditions of the ammonia NH₃ plasma process includes a pressure in a range from about 3 Torr to 6 Torr, a temperature in a range from about 370° C. to 430° C., a nitrogen N₂ flow in a range from about 4800 sccm to 5200 sccm, and ammonia NH₃ flow in a range of about 60 sccm to 90 seem. Although the surface roughness of the seed layer 37 becomes smaller as the processing time extends, the surface roughness may become saturated after the processing time passes 30 seconds.

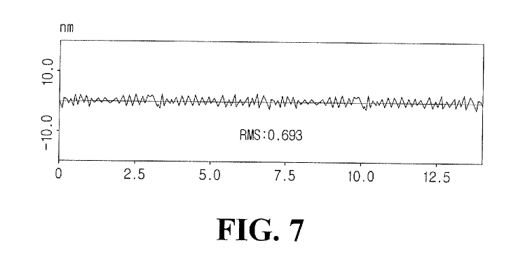

For example, when an ammonia plasma process is performed for about 15 seconds, the surface roughness becomes smaller, for example, about 0.693 RMS, as shown in FIG. 7 compared to the 3.929 RMS (see FIG. 3A) of a seed layer not having an ammonia plasma process performed thereon.

Referring to FIG. 6C, after the ammonia plasma process is performed, copper material 38 can be buried on the seed layer 37 using an electrochemical plating process.

Referring to FIG. 6D, a chemical mechanical polishing process can be performed to expose the interlayer insulating layer 33. Accordingly, the barrier layer 35 and the copper material 38 are removed from the semiconductor substrate 31 except for in the via hole 32, and a copper line 39 is formed in the via hole 32.

As described above, the surface roughness is minimized by performing an ammonia surface process on the seed layer. Therefore, the reliability of a copper wire formed on a seed layer can be improved.

When the terms “on” or “over” are used herein, when referring to layers, regions, patterns, or structures, it is understood that the layer, region, pattern or structure can be directly on another layer or structure, or intervening layers, regions, patterns, or structures may also be present. When the terms “under” or “below” are used herein, when referring to layers, regions, patterns, or structures, it is understood that the layer, region, pattern or structure can be directly under the other layer or structure, or intervening layers, regions, patterns, or structures may also be present.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method of verifying line reliability, comprising:
providing a first substrate and a second substrate;
forming a first seed layer on the first substrate and a second seed layer on the second substrate;
providing a difference in surface roughness between the first seed layer and the second seed layer;
performing a first x-ray diffraction (XRD) analysis on the first seed layer and the second seed layer;
forming a first copper line on the first seed layer and a second copper line on the second seed layer;
performing a second XRD analysis on the first copper line and the second copper line; and
defining line reliability based on the results of the first and second XRD analysis.

2. The method according to claim 1, wherein the surface roughness of the first seed layer is provided to be greater than the surface roughness of the second seed layer.

3. The method according to claim 2, wherein performing the second XRD analysis comprises detecting copper directivity of [2,0,0].

4. The method according to claim 3, wherein copper with a directivity of [2,0,0] is more strongly detected in the first copper line than in the second copper line.

5. The method according to claim 3, wherein defining line reliability comprises defining copper line reliability based on the detection of copper directivity of [2,0,0], wherein the reliability of a copper line becomes reduced as the copper with a directivity of [2,0,0] is more strongly detected.

6. The method according to claim 1, wherein providing a difference in surface roughness comprises performing an ammonia plasma process on the first seed layer or the second seed layer.

7. The method according to claim 6, wherein the ammonia plasma process is performed only on the second seed layer.

8. A method of fabricating a semiconductor device, comprising:
forming an interlayer insulating layer having a via hole on a semiconductor substrate;
forming a seed layer on the interlayer insulating layer including the via hole;
performing an ammonia plasma process on the seed layer to reduce surface roughness of the seed layer; and
forming a copper line using the surface roughness reduced seed layer.

9. The method according to claim 8, wherein performing the ammonia plasma process comprises using a pressure in a range from about 3 Torr to 6 Torr, a temperature in a range from about 370° C. to 430° C., a nitrogen N₂ flow in a range from about 4800 sccm to 5200 sccm, and ammonia NH₃ flow in a range of about 60 sccm to 90 sccm.

10. The method according to claim 8, wherein the ammonia plasma process is performed for about 15 seconds to 30 seconds.

11. The method according to claim 8, further comprising forming a barrier layer on the interlayer insulating layer before forming the seed layer.

12. The method according to claim 8, wherein forming an interlayer insulating layer having a via hole comprises:
depositing insulating layer material on the semiconductor substrate; and
etching the insulating layer material to form a via hole and a trench.
